(19) United States
(12) Patent Application Publication
(10) Pub. No.: US 2025/0268006 A1
(43) Pub. Date: Aug. 21, 2025

(54) TRANSPARENT DISPLAY DEVICE

(71) Applicants: YAS CO., LTD., Gyeonggi-do (KR); O-FLEX CO., LTD, Daejeon (KR)

(72) Inventors: Bumsik KIM, Gyeonggi-do (KR); Byungchul AHN, Seoul (KR); Seungho KANG, Gyeonggi-do (KR); Myungseop KIM, Daejeon (KR); Kwanghee LEE, Daejeon (KR)

(21) Appl. No.: 19/053,142

(22) Filed: Feb. 13, 2025

(30) Foreign Application Priority Data
Feb. 15, 2024 (KR) 10-2024-0021774
Feb. 12, 2025 (KR) 10-2025-0018184

(51) Int. Cl. H10H 29/49

(52) U.S. Cl. CPC H10H 29/49

(57) ABSTRACT

The transparent display device may include a first layer including a first power wiring and a second power wiring along a first direction, a second layer disposed on the first layer and including a third power wiring, a fourth power wiring, a first data signal wiring, a second data signal wiring, and a plurality of connecting wirings along the first direction, a driving IC disposed between the third power wiring and the fourth power wiring, and a light-emitting element disposed between the third power wiring and the fourth power wiring. The first power wiring and the third power wiring may overlap vertically, and the second power wiring and the fourth power wiring may overlap vertically.

### BACKGROUND

### Field of the Disclosure

The embodiment relates to a transparent display device.

### Discussion of the Related Art

Various display devices that implement images are being developed. For example, there are a liquid crystal display (LCD) display device, a light-emitting element display device, and an organic light-emitting diode (OLED) display device.

Meanwhile, an active matrix (AM) type transparent display device that may display images without obstructing the view by transmitting light from the front and back is in the spotlight. In order to implement the AM type transparent display device, various opaque components such as a driving IC, a light-emitting element such as a light-emitting diode (LED), power wirings, and signal wirings are disposed.

There is a problem that the transparency of the transparent display device is reduced due to these various opaque components.

### SUMMARY

An object of the embodiment is to solve the foregoing and other problems.

Another object of the embodiment is to provide a transparent display device that can improve transparency by increasing the transmission area.

The technical problems of the embodiments are not limited to those described in this item and comprise those that can be understood through the description of the invention.

According to one aspect of the embodiment to achieve the above or other objects, a transparent display device, comprising: a first layer comprising a first power wiring and a second power wiring along a first direction; a second layer disposed on the first layer and comprising a third power wiring, a fourth power wiring, a first data signal wiring, a second data signal wiring, and a plurality of connecting wirings along the first direction; a driving IC disposed between the third power wiring and the fourth power wiring; and a light-emitting element disposed between the third power wiring and the fourth power wiring, wherein the driving IC is electrically connected to one of the first power wiring and the third power wiring, one of the second power wiring and the fourth power wiring, the first data signal wiring, the second data signal wiring, and the plurality of connecting wirings, wherein the light-emitting element is electrically connected to one of the second power wiring and the fourth power wiring and the plurality of connecting wirings, and wherein the first power wiring and the third power wiring vertically overlap and the second power wiring and the fourth power wiring vertically overlap.

The transparent display device may further comprise: a substrate having a lower surface on which the first layer is disposed and an upper surface on which the second layer is disposed.

The first power wiring and the second power wiring may be low-potential wirings, and the third power wiring and the fourth power wiring may be high-potential wirings.

The first layer may further comprise: a connecting part configured to electrically connect the first power wiring and the second power wiring across the second data signal wiring along a second direction; and a connecting pattern configured to electrically connect the third power wiring and the fourth power wiring through a first via and a second via in the substrate across the first data signal wiring along the second direction.

The second power wiring may be electrically connected to the driving IC and the light-emitting element through a via in the substrate, and the third power wiring may be electrically connected to the driving IC.

The first power wiring and the second power wiring may be high-potential wirings, and the third power wiring and the fourth power wiring may be low-potential wirings.

The first layer may further comprise: a connecting part configured to electrically connect the first power wiring and the second power wiring across the first data signal wiring along a second direction; and a connecting pattern configured to electrically connect the third power wiring and the fourth power wiring through a first via and a second via in the substrate across the second data signal wiring along the second direction.

The connecting part may be electrically connected to the driving IC through a via in the substrate, and the fourth power wiring may be electrically connected to the driving IC and the light-emitting element.

The first power wiring and the fourth power wiring may be low-potential wirings, and the second power wiring and the third power wiring may be high-potential wirings.

The first layer may further comprise: a first connecting part configured to electrically connect the first power wiring and the fourth power wiring through a first via in the substrate across the first data signal wiring along a second direction; and a second connecting part configured to electrically connect the second power wiring and the third power wiring through a second via in the substrate across the second data signal wiring along the second direction;

The third power wiring may be electrically connected to the driving IC, and the fourth power wiring may be electrically connected to the driving IC and the light-emitting element.

The transparent display device may further comprise: a first substrate having a lower surface on which the first layer is disposed; and a second substrate having an upper surface on which the second layer is disposed, and the driving IC and the light-emitting element may be disposed between the first substrate and the second substrate.

The transparent display device may further comprise: a conductive spacer between the first substrate and the second substrate.

The light-emitting element may comprise a plurality of light-emitting elements that are vertically stacked with each other and electrically connected to the plurality of connecting wirings.

The light-emitting element may comprise a plurality of light-emitting elements that may be disposed horizontally with each other along a second direction and connected to the plurality of connecting wirings.

The effects of the transparent display device according to the embodiment are described as follows.

According to at least one of the embodiments, a first power wiring and a second power wiring on a lower surface of a substrate vertically overlap with a third power wiring and a fourth power wiring on an upper surface of the substrate, respectively, so that the transmission area can increase and the transparency can be improved.

According to at least one of the embodiments, the third power wiring and the fourth power wiring on the upper surface of the substrate may be electrically connected through a connecting pattern disposed on the lower surface of the substrate, so that a first data signal wiring or a second data signal wiring disposed between the third power wiring and the fourth power wiring on the upper surface of the substrate can be prevented from being electrically short-circuited with the third power wiring and the fourth power wiring.

According to at least one of the embodiments, capacitors may be formed by the first power wiring, the substrate, and the third power wiring which are vertically overlapped with each other, and the second power wiring, the substrate, and the fourth power wiring which are vertically overlapped with each other, so that a noise reduction effect that is insensitive to noise can be obtained. Accordingly, signal distortion due to noise does not occur, so that poor image quality can be prevented.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### BRIEF DESCRIPTION OF THE DRAWINGS

FIG. 1 is a cross-sectional view of a transparent display device according to a first embodiment.

FIG. 2 is a plan view of a transparent display device according to the first embodiment.

FIG. 3A illustrates the first layer illustrated in FIG. 2.

FIG. 3B illustrates the second layer illustrated in FIG. 2.

FIG. 4 illustrates the connection relationship between a driving IC and a plurality of light-emitting element chips.

FIG. 5 is a plan view of a transparent display device according to a second embodiment.

FIG. 6A illustrates the first layer illustrated in FIG. 5.

FIG. 6B illustrates the second layer illustrated in FIG. 5.

FIG. 7 is a plan view of a transparent display device according to a third embodiment.

FIG. 8A is a cross-sectional view of the transparent display device illustrated in FIG. 7 taken along line A-A′.

FIG. 8B is a cross-sectional view of the transparent display device illustrated in FIG. 7 taken along line B-B′.

FIG. 9 illustrates a state in which the second power wiring of the first layer and the third power wiring of the second layer are electrically connected to each other along a first direction in the transparent display device illustrated in FIG. 7.

FIG. 10 illustrates a state in which the first power wiring of the first layer and the fourth power wiring of the second layer are electrically connected to each other along a first direction in the transparent display device illustrated in FIG. 7.

FIG. 11 is a plan view of a transparent display device according to a fourth embodiment.

FIG. 12A illustrates the first layer illustrated in FIG. 11.

FIG. 12B illustrates the second layer illustrated in FIG. 11.

FIG. 13 is a cross-sectional view of a transparent display device according to a second embodiment.

FIG. 14A is a cross-sectional view illustrating an example of a transparent display device according to a third embodiment.

FIG. 14B is a cross-sectional view illustrating another example of a transparent display device according to the third embodiment.

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### DETAILED DESCRIPTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

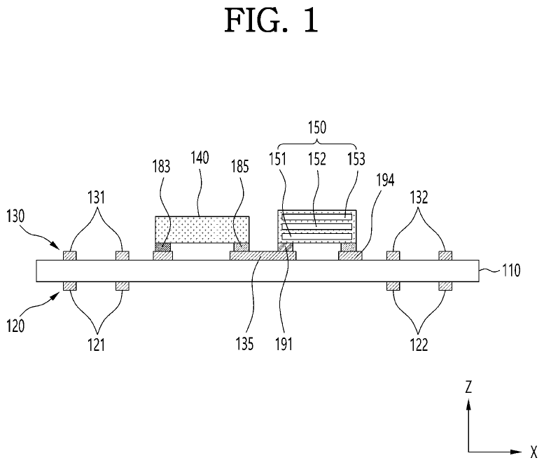

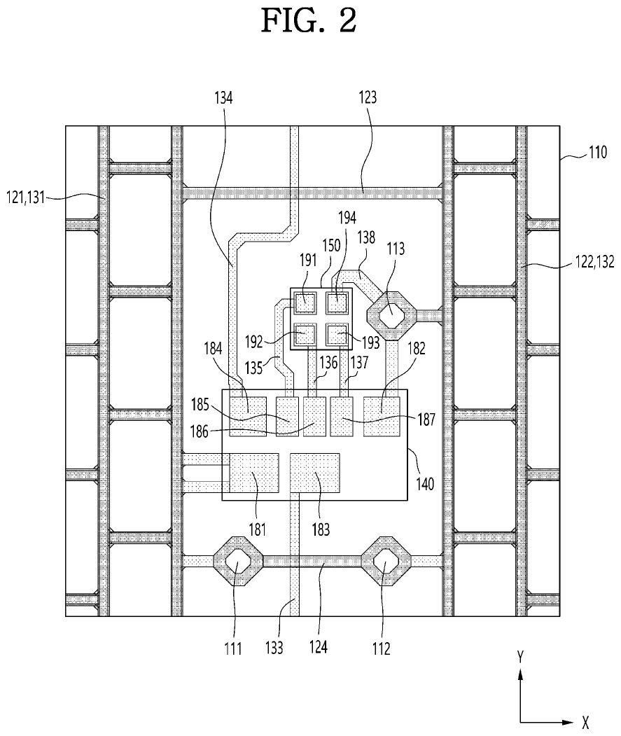

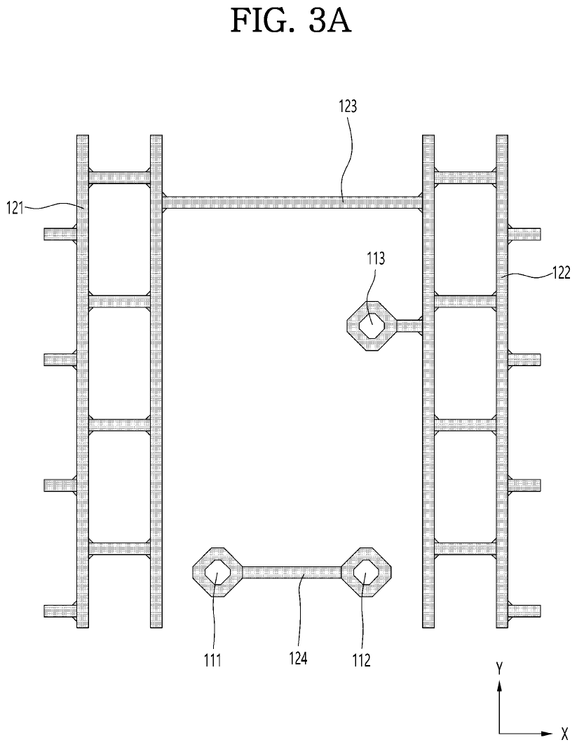

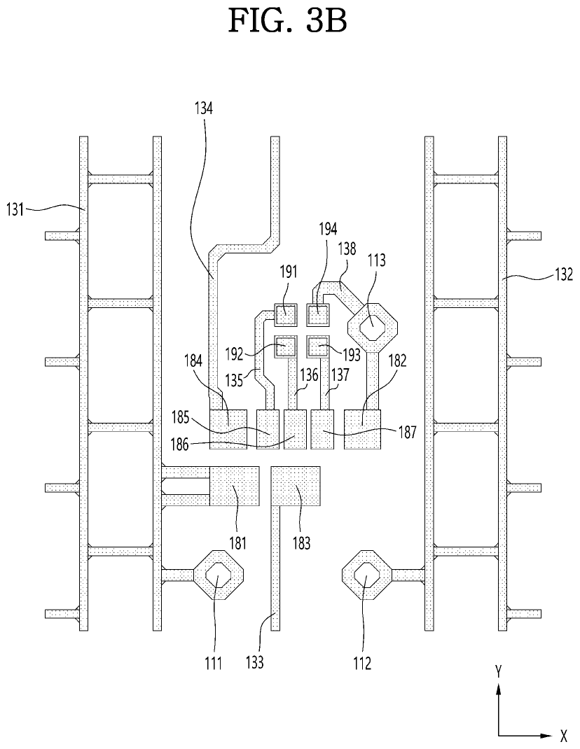

FIG. 1 is a cross-sectional view of a transparent display device according to a first embodiment. FIG. 2 is a plan view of a transparent display device according to the first embodiment. FIG. 3A illustrates the first layer illustrated in FIG. 2, and FIG. 3B illustrates the second layer illustrated in FIG. 2.

In FIG. 2, the transparent display device is illustrated as comprising one pixel. The transparent display device may be configured with the pixel illustrated in FIG. 2 in plural.

Referring to FIGS. 1 and 2, the transparent display device according to the first embodiment may comprise a substrate 110, a first layer 120, a second layer 130, a driving IC 140, a light-emitting element chip 150, etc. The driving IC 140 may be configured as a chip or a die.

The substrate 110 may be a transparent substrate, a flexible substrate, or a rigid substrate. The substrate 110 may be a transparent and flexible substrate. The substrate 110 may be a transparent and rigid substrate.

The substrate 110 may be made of a transparent material. The substrate 110 may be made of a flexible or rigid material. For example, the substrate 110 may be made of plastic, a polymer resin, glass, etc.

A plurality of vias 111 to 113 may be formed in the substrate 110. Each via 111 to 113 may refer to a hole penetrating the substrate 110 or may refer to a conductor such as a metal having excellent electrical conductivity filled in the hole. Each via 111 to 113 may serve to electrically connect the first layer 120 and the second layer 130 by penetrating the substrate 110.

The first layer 120 may be disposed on a lower surface of the substrate 110, and the second layer 130 may be disposed on an upper surface of the substrate 110.

The first layer 120 may have a first power wiring 121 and a second power wiring 122 disposed along the first direction Y. The first power wiring 121 and the second power wiring 122 may be disposed parallel to each other along the first direction Y, but are not limited thereto.

The first power wiring 121 may be a low-potential wiring that supplies a low-potential voltage. The first power wiring 121 may have a mesh shape or a ladder shape. The second power wiring 122 may be a low-potential wiring that supplies a low-potential voltage. The second power wiring 122 may have a mesh shape or a ladder shape.

The first layer 120 may comprise a connecting part 123. The connecting part 123 may be disposed between the first power wiring 121 and the second power wiring 122.

The connecting part 123 may electrically connect the first power wiring 121 and the second power wiring 122 along the second direction X. When the low-potential voltage supplied to the first power wiring 121 is greater than the low-potential voltage supplied to the second power wiring 122, the low-potential voltage supplied to the first power wiring 121 may be supplied to the second power wiring 122 through the connecting part 123. Until the low-potential voltage supplied to the first power wiring 121 and the low-potential voltage supplied to the second power wiring 122 become the same, the low-potential voltage supplied to the first power wiring 121 may be supplied to the second power wiring 122 through the connecting part 123. Therefore, the connecting part 123 may be an equipotential power wiring that makes the low-potential voltage supplied to the first power wiring 121 and the low-potential voltage supplied to the second power wiring 122 become the same.

The first power wiring 121, the second power wiring 122, and the connecting part 123 may be integrally formed of the same metal, but are not limited thereto.

The first layer 120 may comprise a connecting pattern 124. The connecting pattern 124 may be disposed between the first power wiring 121 and the second power wiring 122.

The connecting pattern 124 may be disposed lengthwise along the second direction X. The connecting pattern 124 may be disposed to be spaced apart from the first power wiring 121 and the second power wiring 122, respectively. As will be described later, the connecting pattern 124 may electrically connect a third power wiring 131 and a fourth power wiring 132 of the second layer 130. A first data signal wiring 133 of the second layer 130 may be disposed between the third power wiring 131 and the fourth power wiring 132. The connecting pattern 124 of the first layer 120 may electrically connect the third power wiring 131 and the fourth power wiring 132 without causing an electrical short with the first data signal wiring 133 in the second layer 130.

The first power wiring 121, the second power wiring 122, the connecting part 123, and the connecting pattern 124 may be formed of the same metal using the same photolithography process, but are not limited thereto.

Meanwhile, the second layer 130 may comprise the third power wiring 131, the fourth power wiring 132, the first data signal wiring 133, a second data signal wiring 134, a plurality of connecting wirings 135 to 138, a plurality of pads 181 to 187 and 191 to 194, etc. along the first direction Y.

The third power wiring 131, the fourth power wiring 132, the first data signal wiring 133, the second data signal wiring 134, and the plurality of connecting wirings 135 to 138 may be formed of the same metal using the same photolithography process, but are not limited thereto.

The third power wiring 131 and the fourth power wiring 132 may be disposed parallel to each other along the first direction Y, but are not limited thereto. The first data signal wiring 133 and the second data signal wiring 134 may be disposed in a line along the first direction Y. The first data signal wiring 133 and the second data signal wiring 134 may be disposed parallel to the third power wiring 131 or the fourth power wiring 132 along the first direction Y, but are not limited thereto.

The third power wiring 131 may be a high-potential wiring that supplies a high-potential voltage. The third power wiring 131 may have a mesh shape or a ladder shape.

The fourth power wiring 132 may be a high-potential wiring that supplies a high-potential voltage. The fourth power wiring 132 may have a mesh shape or a ladder shape.

As described above, the first layer 120 may comprise the connecting pattern 124. The connecting pattern 124 may electrically connect the third power wiring 131 and the fourth power wiring 132 via the first via 111 and the second via 112. That is, one side of the connecting pattern 124 of the first layer 120 may be electrically connected to the third power wiring 131 of the second layer 130 via the first via 111, and the other side of the connecting pattern 124 of the first layer 120 may be electrically connected to the fourth power wiring 132 of the second layer 130 via the second via 112.

When the high potential voltage supplied to the third power wiring 131 is greater than the high potential voltage supplied to the fourth power wiring 132, the high potential voltage supplied to the third power wiring 131 may be supplied to the fourth power wiring 132 through the connecting pattern 124 of the first layer 120. When the high potential voltage supplied to the third power wiring 131 and the high potential voltage supplied to the fourth power wiring 132 are the same, the high potential voltage supplied to the third power wiring 131 is not supplied to the fourth power wiring 132 through the connecting pattern 124, and also the high potential voltage supplied to the fourth power wiring 132 is not supplied to the third power wiring 131 through the connecting pattern 124. In other words, the connecting pattern 124 may be an equipotential power wiring that makes the high potential voltage supplied to the third power wiring 131 and the high potential voltage supplied to the fourth power wiring 132 the same.

In an embodiment, a high-potential voltage may be greater than a low-potential voltage. The high-potential voltage may be called the VDD voltage, and the low-potential voltage may be called the VSS voltage. The low-potential voltage may be called the first power voltage, and the high-potential voltage may be called the second power voltage, or vice versa.

Meanwhile, since the first power wiring 121, the second power wiring 122, the third power wiring 131, and the fourth power wiring 132 are usually disposed on the same surface and spaced apart from each other so that an electrical short circuit does not occur, there is a problem that the transparency is lowered due to a decrease in the transmission area of the transparent substrate 110.

However, in an embodiment, the first power wiring 121 of the first layer 120 and the third power wiring 131 of the second layer 130 may be vertically overlapped. The first power wiring 121 of the first layer 120 and the third power wiring 131 of the second layer 130 may be vertically overlapped with the substrate 110 interposed therebetween. The second power wiring 122 of the first layer 120 and the fourth power wiring 132 of the second layer 130 may be vertically overlapped. The second power wiring 122 of the first layer 120 and the fourth power wiring 132 of the second layer 130 may be vertically overlapped with the substrate 110 interposed therebetween. Accordingly, the first power wiring 121 and the second power wiring 122 on the lower surface of the substrate 110 may vertically overlap with the third power wiring 131 and the fourth power wiring 132 on the upper surface of the substrate 110, respectively, so that the transmission area can increase and the transparency can be improved.

In addition, in the embodiment, the substrate 110 may have a permittivity. In this instance, a first capacitor may be formed by the first power wiring 121, the third power wiring 131, and the substrate 110 between the first power wiring 121 and the third power wiring 131, and a second capacitor may be formed by the second power wiring 122, the fourth power wiring 132, and the substrate between the second power wiring 122 and the fourth power wiring 132. Accordingly, a noise reduction effect that makes noise insensitive may be obtained due to the first capacitor and the second capacitor. Accordingly, signal distortion due to noise may not occur, and poor image quality can be prevented.

Meanwhile, the first data signal wiring 133 and the second data signal wiring 134 may serve to supply a data signal. As will be described later, the first data signal wiring 133 and the second data signal wiring 134 may be connected to the driver IC 140. In this instance, the first data signal wiring 133 may be an input data signal wiring for inputting a data signal to the driver IC 140, and the second data signal wiring 134 may be an output data signal wiring for outputting a data signal from the driver IC 140 to another driver IC 140 of the next pixel.

The first data signal wiring 133 and the second data signal wiring 134 electrically connected to the driver IC 140 may be disposed for each of a plurality of pixels (not illustrated) disposed along the first direction Y.

The first data signal wiring 133 and the second data signal wiring 134 may be disposed between the third power wiring 131 and the fourth power wiring 132, respectively. As described above, the connecting pattern 124 may electrically connect the third power wiring 131 and the fourth power wiring 132 through the first via 111 and the second via 112 in the substrate 110. Accordingly, the third power wiring 131 and the fourth power wiring 132 can be prevented from being electrically shorted with the first data signal wiring 133.

Since the second data signal wiring 134 is disposed in the second layer 130, even if the connecting part 123 of the first layer 120 crosses the second data signal wiring 134, the connecting part 123 of the first layer 120 can be prevented from being electrically shorted with the second data signal wiring 134.

Meanwhile, a plurality of connecting wirings 135 to 138 may be disposed between the third power wiring 131 and the fourth power wiring 132. The plurality of connecting wirings 135 to 138 may electrically connect the driving IC 140 and the light-emitting element chip 150.

The fourth connecting wiring 138 may be electrically connected to the second power wiring 122 through the via 113 in the substrate 110. In addition, the fourth connecting wiring 138 may be electrically connected to the driving IC 140 and the light-emitting element chip 150.

A plurality of pads 181 to 187 and 191 to 194 may be disposed in a region where the driving IC 140 is positioned and a region where the light-emitting element chip 150 is positioned.

A plurality of pads 181 to 187 may be disposed on a first region of the substrate 110 between the third power wiring 131 and the fourth power wiring 132. A driving IC 140 may be disposed on the first region and may be physically attached to and electrically connected to the plurality of pads 181 to 187. The plurality of pads 181 to 187 may be electrically connected to the third power wiring 131, the first data signal wiring 133, the second data signal wiring 134, and the plurality of connecting wirings 135 to 138.

A plurality of pads 191 to 194 may be disposed on a second region of the substrate 110 between the third power wiring 131 and the fourth power wiring 132. The light-emitting element chip 150 may be disposed on the second region and may be physically attached to and electrically connected to the plurality of pads 191 to 194. The physical attachment may be possible using a die bonding method, but is not limited thereto.

The first pad 191 of the second region may be electrically connected to the fifth pad 185 of the first region via the first connecting wiring 135, the second pad 192 of the second region may be electrically connected to the sixth pad 186 of the first region via the second connecting wiring 136, and the third pad 193 of the second region may be electrically connected to the seventh pad 187 of the first region via the third connecting wiring 137. The fourth pad 194 of the second region may be electrically connected to the second pad 182 of the first region via the fourth connecting wiring 138. The fourth pad 194 may be electrically connected to the second power wiring 122 of the first layer 120 via the fourth connecting wiring 138 and a via 113 in the substrate 110. Accordingly, a low-potential voltage may be supplied from the second power wiring 122 to the second pad 182 of the first region and the fourth pad 194 of the second region.

Meanwhile, the third power wiring 131 may be electrically connected to the first pad 181 of the first region, so that a high-potential voltage may be supplied from the third power wiring 131 to the first pad 181. The first data signal wiring 133 may be electrically connected to the third pad 183 of the first region, so that a data signal may be transmitted to the driving IC 140 through the third pad 183. The driving IC 140 may generate driving signals according to the data signal and transmits the driving signals to the light-emitting element chip 150, and the light-emitting element chip 150 may emit light in response to the driving signals. The driving signals may be driving currents, but is not limited thereto. The second data signal wiring 134 may be electrically connected to the fourth pad 184 of the first region, so that the data signal may be transmitted to the next pixel through the second data signal wiring 134.

The light-emitting element chip 150 may be a member that emits light. In an embodiment, the light-emitting element chip 150 may be a semiconductor light-emitting element chip 150 formed of an inorganic semiconductor material.

As illustrated in FIG. 1, the light-emitting element chip 150 may comprise a plurality of light-emitting elements 151 to 153 that are vertically stacked with each other.

A first light-emitting element 151 may comprise a red light-emitting element that emits red light, a second light-emitting element 152 may comprise a green light-emitting element that emits green light, and a third light-emitting element 153 may comprise a blue light-emitting element that emits blue light, but is not limited thereto.

The second light-emitting element 152 may be disposed on an upper side of the first light-emitting element 151, and the third light-emitting element 153 may be disposed on an upper side of the first light-emitting element. In this instance, the red light generated from the first light-emitting element 151 may be emitted forward via the second light-emitting element 152 and the third light-emitting element 153, the green light generated from the second light-emitting element 152 may be emitted forward via the third light-emitting element 153, and the blue light generated from the third light-emitting element 153 may be emitted directly forward.

As described above, the driving IC 140 may generate driving signals (or driving currents) according to the data signals and transmit the data signals to the light-emitting element chip 150. The luminance may vary depending on the intensity of the driving signal (or driving current), allowing for grayscale representation.

The driving signals may be a first driving signal, a second driving signal, and a third driving signal. The first driving signal, the second driving signal, and the third driving signal may be different from each other.

The first light-emitting element 151 may emit red light in response to the first driving signal, the second light-emitting element 152 may emit green light in response to the second driving signal, and the third light-emitting element 153 may emit blue light in response to the third driving signal.

The first pad 191 to the third pad 193 may be electrically connected to the anode electrodes of the first light-emitting element 151, the second light-emitting element 152, and the third light-emitting element 153, which are vertically overlapped, respectively. The anode electrode of the first light-emitting element 151 may be electrically connected to the first connecting wiring 135 via the first pad 191, the anode electrode of the second light-emitting element 152 may be electrically connected to the second connecting wiring 136 via the second pad 192, and the anode electrode of the third light-emitting element 153 may be electrically connected to the third connecting wiring 137 via the third pad 193.

The fourth pad 194 may be commonly connected to the cathode electrodes of the first light-emitting element 151, the second light-emitting element 152, and the third light-emitting element 153, which are vertically overlapped. Accordingly, the fourth pad 194 may be called a common pad, but is not limited thereto.

The driving IC 140 and the light-emitting element chip 150 may be surrounded by the first power wiring 121 (or the third power wiring 131), the second power wiring 122 (or the fourth power wiring 132), the connecting part 123, and the connecting pattern 124. That is, with respect to the driving IC 140 and the light-emitting element chip 150, respectively, the first power wiring 121 may be disposed at the left side thereof, the second power wiring 122 may be disposed at the right side thereof, the connecting part 123 may be disposed on the front side thereof, and the connecting pattern 124 may be disposed on the rear side thereof.

In an embodiment, the light-emitting element chip 150 may be configured as a single chip or die in which a plurality of light-emitting elements 151 to 153 are packaged in a stacked manner. Although the drawing illustrates one light-emitting element chip 150 in which a plurality of light-emitting elements 151 to 153 are packaged in a stacked manner, two or more light-emitting element chips may be provided. That is, two or more light-emitting element chips may be provided between the third power wiring 131 and the fourth power wiring 132.

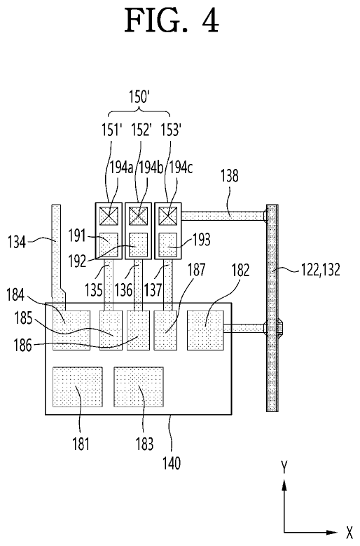

Alternatively, as illustrated in FIG. 4, the light-emitting element chip 150′ may comprise a first light-emitting element chip 151′, a second light-emitting element chip 152′, and a third light-emitting element chip 153′, each of which is individually configured as a chip or die. In this instance, the first light-emitting element chip 151′, the second light-emitting element chip 152′, and the third light-emitting element chip 153′ may be disposed horizontally to each other along the second direction X. To this end, a plurality of common pads 194a, 194b, and 194c may be electrically connected to the fourth connecting wiring 138. For example, the fourth connecting wiring 138 may be disposed lengthwise along the second direction X, and the first region, the second region, and a third region of the fourth connecting wiring 138 may be allocated to a plurality of common pads 194a, 194b, and 194c.

The first pad 191 to the third pad 193 may be disposed to horizontally correspond to each of the plurality of common pads 194a, 194b, and 194c. In this instance, the first light-emitting element chip 151′ may be physically attached and electrically connected to the first pad 191 and the common pad 194a. The second light-emitting element chip 152′ may be physically attached and electrically connected to the second pad 192 and the common pad 194b. The third light-emitting element chip 153′ may be physically attached and electrically connected to the third pad 193 and the common pad 194c.

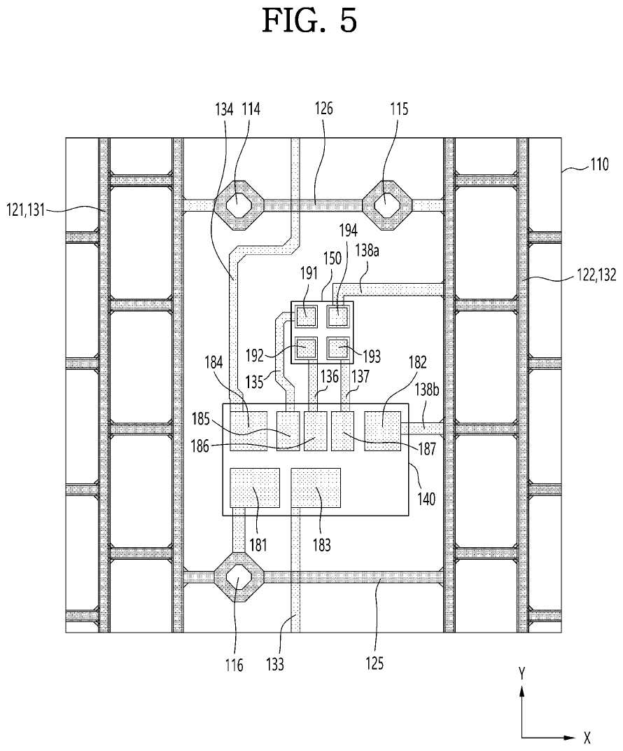

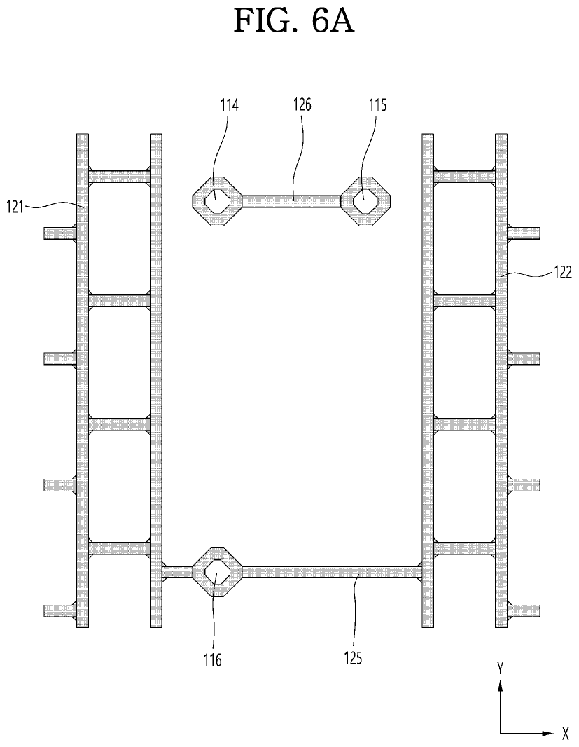

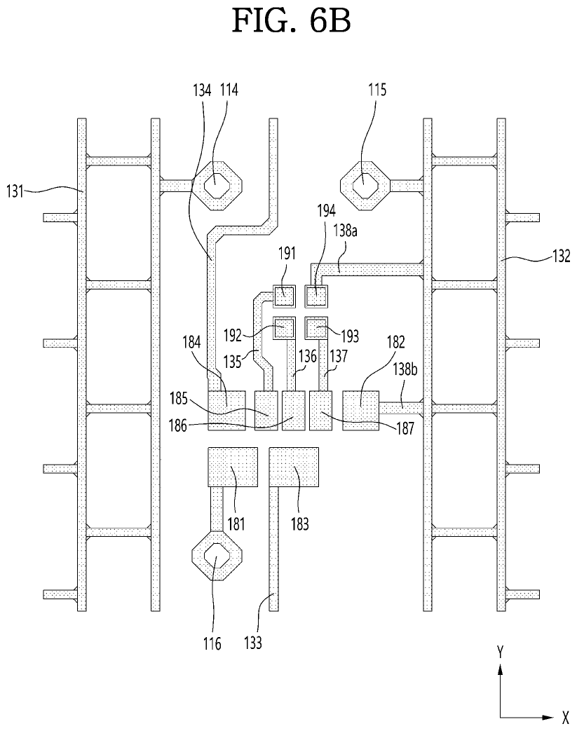

FIG. 5 is a plan view of a transparent display device according to a second embodiment. FIG. 6A illustrates the first layer illustrated in FIG. 5, and FIG. 6B illustrates the second layer illustrated in FIG. 5.

In FIG. 5, the transparent display device is illustrated as comprising one pixel. The transparent display device may be configured with the pixel illustrated in FIG. 5 in plural.

Although a cross-sectional view of the transparent display device according to the second embodiment is not illustrated, the cross-sectional view may be identical to the cross-sectional view illustrated in FIG. 1.

The second embodiment is the same as the first embodiment (FIGS. 2 to 3B) except that the first power wiring 121 and the second power wiring 122 are high-potential wirings and the third power wiring 131 and the fourth power wiring 132 are low-potential wirings. In the second embodiment, components having the same shape, structure, and/or function as those in the first embodiment (FIGS. 2 to 3B) are given the same drawing reference numerals, and detailed descriptions are omitted. The omitted descriptions related to the second embodiment below may be easily understood from the descriptions of the first embodiment (FIGS. 2 to 3B).

Referring to FIGS. 1 and 5, a transparent display device according to the second embodiment may comprise a substrate 110, a first layer 120, a second layer 130, a driving IC 140, a light-emitting element chip 150, etc.

The first layer 120 may be disposed on the lower surface of the substrate 110, and the second layer 130 may be disposed on the upper surface of the substrate 110.

As illustrated in FIG. 6A, the first layer 120 may comprise a first power wiring 121, a second power wiring 122, a connecting part 125, a connecting pattern 126, etc.

The first power wiring 121 and the second power wiring 122 may be disposed along the first direction Y, and the connecting part 125 and the connecting pattern 126 may be disposed along the second direction X. The connecting part 125 and the connecting pattern 126 may be disposed between the first power wiring 121 and the second power wiring 122.

The connecting part 125 may electrically connect the first power wiring 121 and the second power wiring 122 across a first data signal line 133 of the second layer 130 along the second direction X. The connecting pattern 126 may electrically connect a third power wiring 131 and a fourth power wiring 132 of the second layer 130 through a first via 114 and a second via 115 in the substrate 110 across a second data signal line 134 along the second direction X. Accordingly, the third power wiring 131 and the fourth power wiring 132 can be prevented from being electrically shorted with the second data signal line 134.

The connecting part 125 may be electrically connected to the driving IC 140 through the via 116, pad 181, etc. in the substrate 110. Accordingly, the first power wiring 121 and the second power wiring 122 of the first layer 120 may be electrically connected to the driving IC 140 through the connecting part 125. A high-potential voltage supplied to the first power wiring 121 and the second power wiring 122 may be supplied to the driving IC 140 through the connecting part 125.

The fourth power wiring 132 may be electrically connected to the driving IC 140 and the light-emitting element chip 150. The fourth power wiring 132 may be electrically connected to the light-emitting element chip 150 through a fourth connecting wiring 138a, the fourth pad 194, etc. A low-potential voltage supplied to the fourth power wiring 132 may be supplied to the light-emitting element chip 150 through the fourth connecting wiring 138a. The fourth power wiring 132 may be electrically connected to the driver IC 140 through another fourth connecting wiring 138b, the second pad 192, etc. The low-potential voltage supplied to the fourth power wiring 132 may be supplied to the driver IC 140 through another fourth connecting wiring 138b.

As illustrated in FIG. 6B, the second layer 130 may comprise a third power wiring 131, a fourth power wiring 132, a first data signal wiring 133, a second data signal wiring 134, a plurality of connecting wirings 135 to 138, a plurality of pads 181 to 187 and 191 to 194, etc.

The third power wiring 131, the fourth power wiring 132, the first data signal wiring 133, and the second data signal wiring 134 may be disposed along the first direction Y.

The first data signal wiring 133 and the second data signal wiring 134 may be disposed between the third power wiring 131 and the fourth power wiring 132.

As described above, in the first embodiment (FIGS. 2 to 3B), the first power wiring 121 and the second power wiring 122 may be low-potential wirings, and the third power wiring 131 and the fourth power wiring 132 may be high-potential wirings.

However, as illustrated in FIGS. 5, 6A, and 6B, in the second embodiment, the first power wiring 121 and the second power wiring 122 may be high-potential wirings, and the third power wiring 131 and the fourth power wiring 132 may be low-potential wirings.

Meanwhile, in the embodiment, the first power wiring 121 of the first layer 120 and the third power wiring 131 of the second layer 130 may be vertically overlapped. The first power wiring 121 of the first layer 120 and the third power wiring 131 of the second layer 130 may be vertically overlapped with the substrate 110 interposed therebetween. The second power wiring 122 of the first layer 120 and the fourth power wiring 132 of the second layer 130 may be vertically overlapped. The second power wiring 122 of the first layer 120 and the fourth power wiring 132 of the second layer 130 may be vertically overlapped with the substrate 110 interposed therebetween. Accordingly, the first power wiring 121 and the second power wiring 122 on the lower surface of the substrate 110 may vertically overlap with the third power wiring 131 and the fourth power wiring 132 on the upper surface of the substrate 110, respectively, so that the transmission area can increase and the transparency can be improved.

In addition, in the embodiment, the substrate 110 may have a permittivity. In this instance, a first capacitor may be formed by the first power wiring 121, the third power wiring 131, and the substrate 110 between the first power wiring 121 and the third power wiring 131, and a second capacitor may be formed by the second power wiring 122, the fourth power wiring 132, and the substrate between the second power wiring 122 and the fourth power wiring 132. Accordingly, a noise reduction effect that makes noise insensitive may be obtained due to the first capacitor and the second capacitor. Therefore, signal distortion due to noise does not occur, so that poor image quality can be prevented.

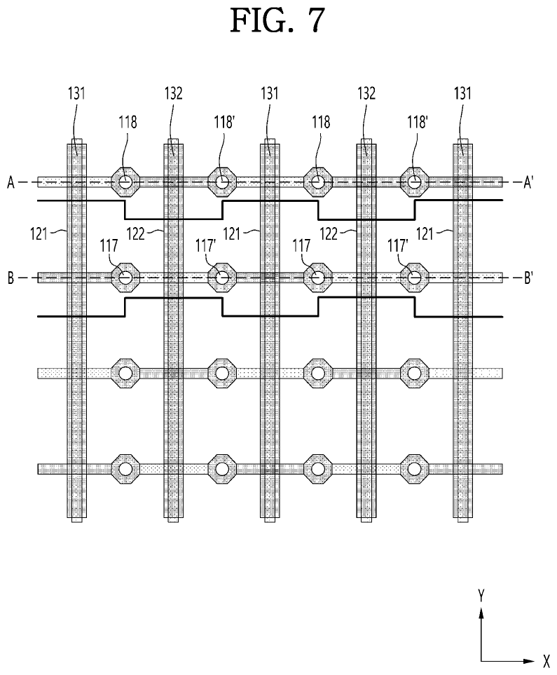

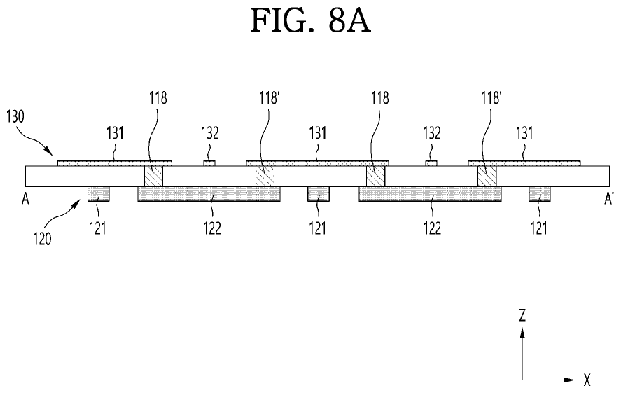

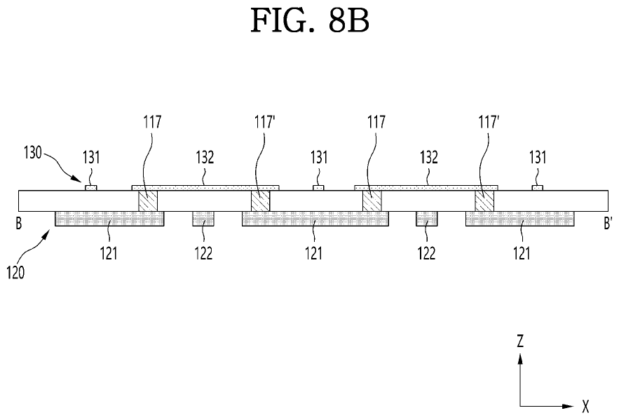

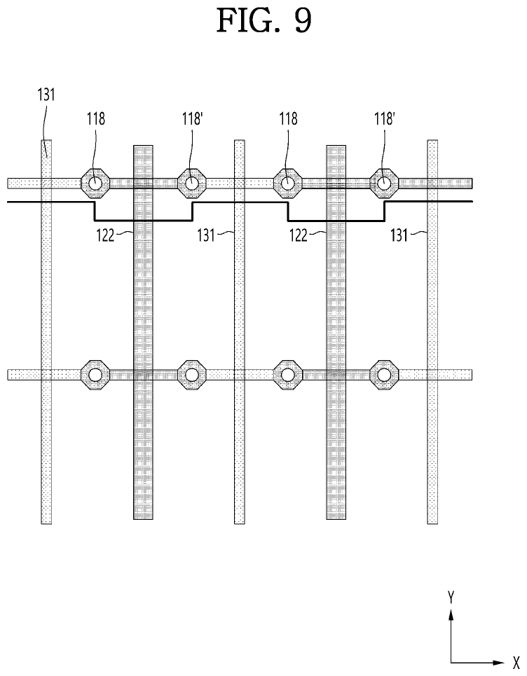

FIG. 7 is a plan view of a transparent display device according to a third embodiment. FIG. 8A is a cross-sectional view of the transparent display device illustrated in FIG. 7 taken along line A-A′. FIG. 8B is a cross-sectional view of the transparent display device illustrated in FIG. 7 taken along line B-B′. FIG. 9 illustrates a state in which the second power wiring of the first layer and the third power wiring of the second layer are electrically connected to each other along a first direction in the transparent display device illustrated in FIG. 7.

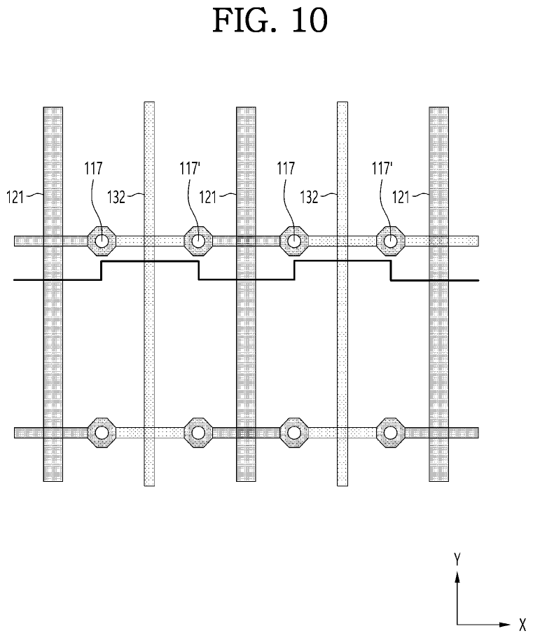

FIG. 10 illustrates a state in which the first power wiring of the first layer and the fourth power wiring of the second layer are electrically connected to each other along a first direction in the transparent display device illustrated in FIG. 7.

Referring to FIG. 7, FIG. 8A, and FIG. 8B, the transparent display device according to the third embodiment may comprise a substrate 110, a first layer 120, a second layer 130, etc.

The first layer 120 may be disposed on the lower surface of the substrate 110, and the second layer 130 may be disposed on the upper surface of the substrate 110. The first layer 120 may comprise a plurality of first power wirings 121, a plurality of second power wirings 122, etc., and the second layer 130 may comprise a plurality of third power wirings 131, a plurality of fourth power wirings 132, etc.

Although not illustrated, a plurality of pixels may be provided between the plurality of third power wirings 131 and the plurality of fourth power wirings 132. That is, a plurality of pixels may be provided along the first direction Y between adjacent third power wirings 131 and fourth power wirings 132. A plurality of pixels may be provided along the first direction Y between another adjacent third power wiring 131 and fourth power wiring 132.

Although not illustrated, a plurality of pixels may be provided with a driving IC 140 and a light-emitting element chip 150, respectively. The driving IC 140 and the light-emitting element chip 150 may be provided on the upper surface of the substrate 110.

A plurality of first power wirings 121 and a plurality of second power wirings 122 may be disposed on the lower surface of the substrate 110. The plurality of first power wirings 121 and the plurality of second power wirings 122 may be disposed parallel to each other along the first direction Y, but are not limited thereto.

A plurality of third power wirings 131 and a plurality of fourth power wirings 132 may be disposed parallel to each other along the first direction Y, but are not limited thereto.

In an embodiment, the plurality of first power wirings 121 of the first layer 120 and the plurality of third power wirings 131 of the second layer 130 may be vertically overlapped, respectively. The plurality of first power wirings 121 of the first layer 120 and the plurality of third power wirings 131 of the second layer 130 may be vertically overlapped, respectively, with the substrate 110 interposed therebetween. The plurality of second power wirings 122 of the first layer 120 and the plurality of fourth power wirings 132 of the second layer 130 may be vertically overlapped, respectively. The plurality of second power wirings 122 of the first layer 120 and the plurality of fourth power wirings 132 of the second layer 130 may be vertically overlapped, respectively, with the substrate 110 interposed therebetween. Accordingly, the plurality of first power wirings 121 on the lower surface of the substrate 110 may vertically overlap with the plurality of third power wirings 131 on the upper surface of the substrate 110, and the plurality of third power wirings 131 on the lower surface of the substrate 110 may vertically overlap with the plurality of fourth power wirings 132 on the upper surface of the substrate 110, respectively, so that the transmission area can increase and the transparency can be improved.

In addition, in the embodiment, the substrate 110 may have a permittivity. In this instance, a first capacitor may be formed by the first power wiring 121, the third power wiring 131, and the substrate 110 between the first power wiring 121 and the third power wiring 131, and a second capacitor may be formed by the second power wiring 122, the fourth power wiring 132, and the substrate between the second power wiring 122 and the fourth power wiring 132. Accordingly, a noise reduction effect that makes noise insensitive may be obtained due to the first capacitor and the second capacitor. Therefore, signal distortion due to noise does not occur, so that poor image quality can be prevented.

Meanwhile, a plurality of first power wirings 121 and a plurality of second power wirings 122 may be alternately disposed on the lower surface of the substrate 110 along the second direction X. A plurality of third power wirings 131 and a plurality of fourth power wirings 132 may be alternately disposed on the upper surface of the substrate 110 along the second direction X.

In the embodiment, the first power wiring 121 and the fourth power wiring 132 may be low-potential wirings, and the second power wiring 122 and the fourth power wiring 132 may be high-potential wirings, but the opposite may also be true.

In this instance, as illustrated in FIG. 8A and FIG. 9, a plurality of second power wirings 122 of the first layer 120 and a plurality of third power wirings 131 of the second layer 130 may be electrically connected through a plurality of first vias 118 and a plurality of second vias 118′ in the substrate 110. For example, the third power wiring 131 of the second layer 130 may be electrically connected to one side of the second power wiring 122 of the first layer 120 through the first via 118 in the substrate 110. The other side of the second power wiring 122 of the first layer 120 may be electrically connected to one side of another third power wiring 131 of the second layer 130 through the second via 118′ in the substrate 110. The other side of the third power wiring 131 of the second layer 130 may be connected to one side of the second power wiring 122 of the first layer 120 via the first via 118. Accordingly, a first supply path may be formed in which a high potential voltage is alternately supplied to the upper surface and the lower surface of the substrate 110 along the second direction X.

As illustrated in FIG. 8B and FIG. 10, a plurality of first power wirings 121 of the first layer 120 and a plurality of fourth power wirings 132 of the second layer 130 may be electrically connected via a plurality of first vias 117 and a plurality of second vias 117′ in the substrate 110. For example, a first power wiring 121 of a first layer 120 may be electrically connected to one side of a fourth power wiring 132 of a second layer 130 via a first via 117 on a substrate 110. The other side of the fourth power wiring 132 of the second layer 130 may be electrically connected to one side of another first power wiring 121 of the first layer 120 via a second via 117′ in the substrate 110. The other side of another first power wiring 121 of the first layer 120 may be connected to one side of another fourth power wiring 132 of the second layer 130 via the first via 117. Accordingly, a second supply path may be formed through which a low-potential voltage is alternately supplied to the upper surface and the lower surface of the substrate 110 along the second direction X.

Among the first power wirings 121 of the first layer 120 and the third power wirings 131 of the second layer 130 that are vertically overlapped with each other along the first direction Y, the first power wiring 121 may be electrically connected to the fourth power wiring 132 of the adjacent second layer 130, and the third power wiring 131 may be electrically connected to the second power wiring 122 of the adjacent first layer 120, which may be alternately performed for each row line.

Among the second power wiring 122 of the first layer 120 and the fourth power wiring 132 of the second layer 130, which are vertically overlapped along the first direction Y, the second power wiring 122 may be electrically connected to the third power wiring 131 of the adjacent second layer 130, and the fourth power wiring 132 may be electrically connected to the first power wiring 121 of the adjacent first layer 120, alternately.

Meanwhile, at one end of the substrate 110, the first power wiring 121 and the fourth power wiring 132 may be electrically connected to a low-voltage supply unit (or a low-voltage supply pad) that supplies a low-potential voltage, and the second power wiring 122 and the third power wiring 131 may be electrically connected to a high-potential supply unit (or a high-potential supply pad) that supplies a high-potential voltage. The low-potential supply unit and the high-potential supply unit may be disposed on the upper surface of the substrate 110. In this instance, the first power wiring 121 and the second power wiring 122 disposed on the lower surface of the substrate 110 may be electrically connected to the low-potential supply unit and the high-potential supply unit through their corresponding vias in the substrate 110, respectively.

Meanwhile, as the number of vias increases, the IR drop may increase due to resistance loss. However, in the embodiment, among the plurality of first power wirings 121 disposed on the lower surface of the substrate 110, only the first power wiring 121 electrically connected to the fourth power wiring 132 disposed on the upper surface of the substrate 110 requires its corresponding via to electrically connect to the low-potential supply unit on the upper surface of the substrate 110. In addition, among the plurality of second power wirings 122 disposed on the lower surface of the substrate 110, only the second power wiring 122 electrically connected to the third power wiring 131 disposed on the upper surface of the substrate 110 requires a corresponding via to electrically connect to the high-potential supply section on the upper surface of the substrate 110. Accordingly, the number of vias may be reduced, so that the IR drop can be alleviated or minimized.

In particular, even if the first power wiring 121 and/or the second power wiring 122 disposed on the lower surface of the substrate 110 and the third power wiring 131 and/or the fourth power wiring 132 disposed on the upper surface of the substrate 110 have different thicknesses, the resistance on the first supply path and the resistance on the second supply path may be made the same through the connection structure between the first power wiring 121 and the fourth power wiring 132 and the connection structure between the second power wiring 122 and the third power wiring 131 described above. Accordingly, since the IR drop is used symmetrically not only in the pixel but also in the upper and lower surfaces of the substrate 110, uniform image quality can be secured.

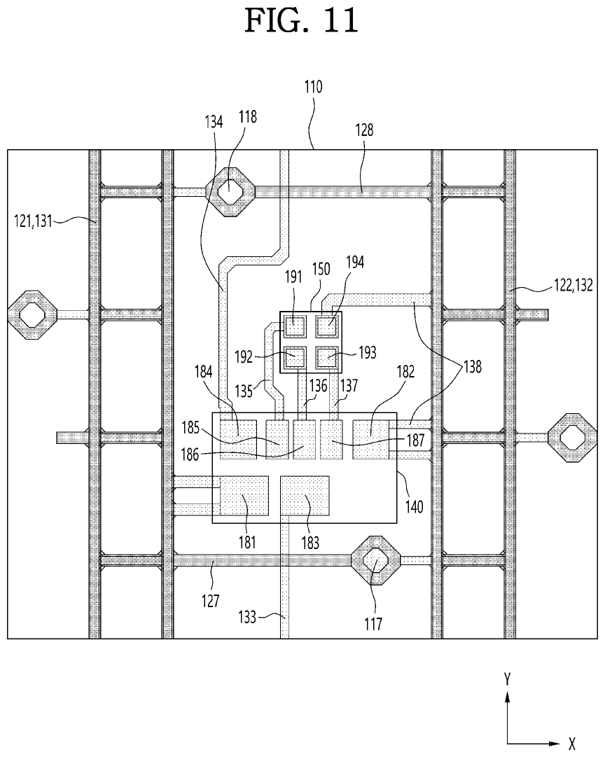

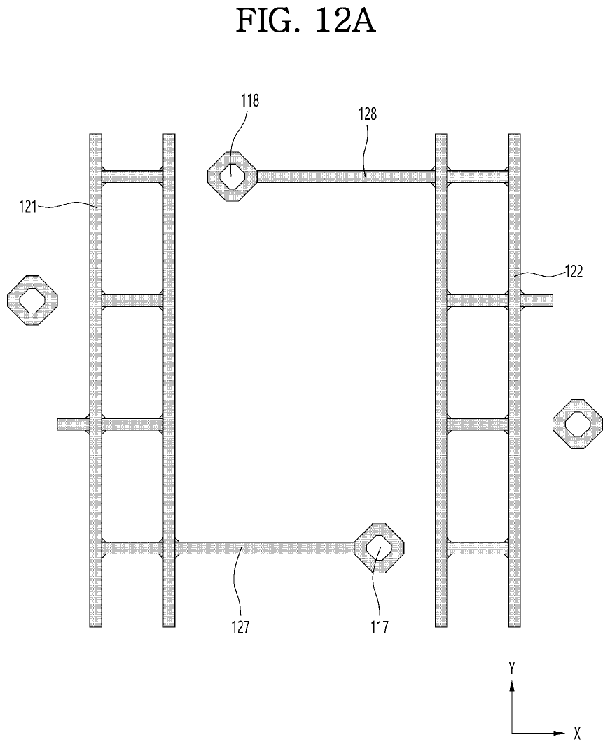

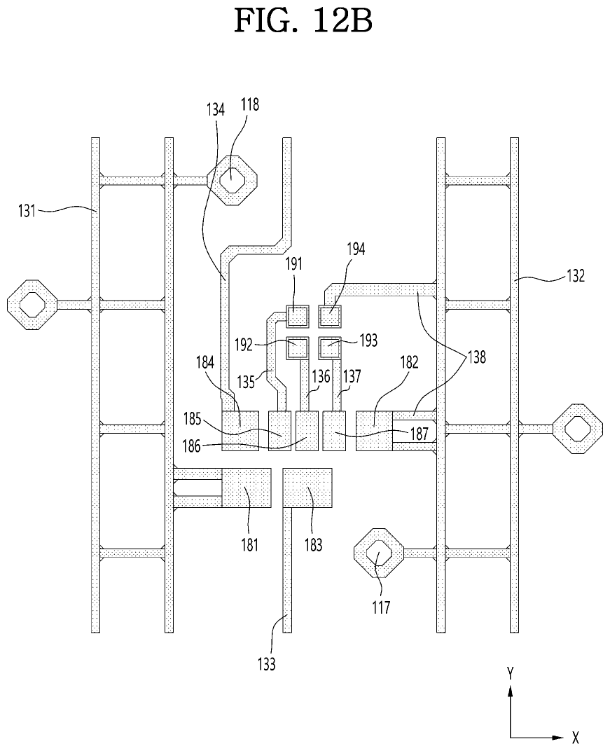

FIG. 11 is a plan view of a transparent display device according to a fourth embodiment. FIG. 12A illustrates the first layer illustrated in FIG. 11, and FIG. 12B illustrates the second layer illustrated in FIG. 11.

In FIG. 11, the transparent display device is illustrated as comprising one pixel. The transparent display device may be configured with the pixel illustrated in FIG. 11 in plural.

Although a cross-sectional view of the transparent display device according to the fourth embodiment is not illustrated, the cross-sectional view may be the same as the cross-sectional view illustrated in FIG. 1.

Referring to FIG. 1 and FIG. 11, the transparent display device according to the fourth embodiment may comprise a substrate 110, a first layer 120, a second layer 130, a driving IC 140, a light-emitting element chip 150, etc.

The first layer 120 may be disposed on the lower surface of the substrate 110, and the second layer 130 may be disposed on the upper surface of the substrate 110.

As illustrated in FIG. 12A, the first layer 120 may comprise a first power wiring 121, a second power wiring 122, a first connecting part 127, a second connecting part 128, etc.

The first power wiring 121 and the second power wiring 122 may be disposed along the first direction Y, and the first connecting part 127 and the second connecting part 128 may be disposed along the second direction X. The first connecting part 127 and the second connecting part 128 may be disposed between the first power wiring 121 and the second power wiring 122.

As illustrated in FIG. 12B, the second layer 130 may comprise a third power wiring 131, a fourth power wiring 132, a first data signal wiring 133, a second data signal wiring 134, a plurality of connecting wirings 135 to 138, a plurality of pads 181 to 187 and 191 to 194, etc.

The third power wiring 131, the fourth power wiring 132, the first data signal wiring 133, and the second data signal wiring 134 may be disposed along the first direction Y.

In an embodiment, the first power wiring 121 of the first layer 120 and the third power wiring 131 of the second layer 130 may be vertically overlapped. The first power wiring 121 of the first layer 120 and the third power wiring 131 of the second layer 130 may be vertically overlapped with the substrate 110 interposed therebetween. The second power wiring 122 of the first layer 120 and the fourth power wiring 132 of the second layer 130 may be vertically overlapped. The second power wiring 122 of the first layer 120 and the fourth power wiring 132 of the second layer 130 may be vertically overlapped with the substrate 110 interposed therebetween. Accordingly, the first power wiring 121 and the second power wiring 122 on the lower surface of the substrate 110 may vertically overlap with the third power wiring 131 and the fourth power wiring 132 on the upper surface of the substrate 110, respectively, so that the transmission area can increase and the transparency can be improved.

In addition, in the embodiment, the substrate 110 may have a permittivity. In this instance, a first capacitor may be formed by the first power wiring 121, the third power wiring 131, and the substrate 110 between the first power wiring 121 and the third power wiring 131, and a second capacitor may be formed by the second power wiring 122, the fourth power wiring 132, and the substrate between the second power wiring 122 and the fourth power wiring 132. Accordingly, a noise reduction effect that makes noise insensitive may be obtained due to the first capacitor and the second capacitor. Accordingly, signal distortion due to noise may not occur, and poor image quality can be prevented.

Meanwhile, in the first embodiment (FIGS. 2 to 3B), the first power wiring 121 and the second power wiring 122 of the first layer 120 may be low-potential wirings, and the third power wiring 131 and the fourth power wiring 132 of the second layer 130 may be high-potential wirings. In the second embodiment (FIGS. 5 to 6B), the first power wiring 121 and the second power wiring 122 of the first layer 120 may be high-potential wirings, and the third power wiring 131 and the fourth power wiring 132 of the second layer 130 may be low-potential wirings.

In contrast, in the fourth embodiment (FIGS. 11 to 12B), the first power wiring 121 and the fourth power wiring 132 may be low-potential wirings, and the second power wiring 122 and the third power wiring 131 may be high-potential wirings.

The first power wiring 121 disposed on the lower surface of the substrate 110 may be a low-potential wiring, and the second power wiring 122 disposed on the lower surface of the substrate 110 may be a high-potential wiring. The third power wiring 131 disposed on the upper surface of the substrate 110 and vertically overlapping the first power wiring 121 may be a high-potential wiring. The fourth power wiring 132 disposed on the upper surface of the substrate 110 and vertically overlapping the second power wiring 122 may be a low-potential wiring.

In this instance, the first power wiring 121 may be electrically connected to the fourth power wiring 132, and the second power wiring 122 may be electrically connected to the third power wiring 131.

To this end, the first layer 120 may comprise a first connecting part 127, a second connecting part 128, etc. The first connecting part 127 and the second connecting part 128 may be disposed between the first power wiring 121 and the second power wiring 122. The first connecting part 127 and the second connecting part 128 may be disposed parallel to each other along the second direction X.

The first connecting part 127 may be disposed to extend from the first power wiring 121 across a first data signal wiring 133 along a second positive (+) direction X, but be spaced apart from the second power wiring 122. The second connecting part 128 may be disposed to extend from the second power wiring 122 across a second data signal wiring 134 along a second negative (−) direction X, but spaced apart from the first power wiring 121.

The first connecting part 127 may be disposed across the first data signal wiring 133 of the second layer 130. The first connecting part 127 may electrically connect the first power wiring 121 and the fourth power wiring 132 via a first via 117 in the substrate 110. The first via 117 may be positioned on a part of the first connecting part 127. The second connecting part 128 may be disposed across the second data signal wiring 134 of the second layer 130. The second connecting part 128 may electrically connect the second power wiring 122 and the third power wiring 131 through a second via 118 in the substrate 110. The second via 118 may be positioned on a part of the second connecting part 128.

Through the arrangement structure of the first connecting part 127 and the second connecting part 128 described above, and the arrangement position of the first via 117 and the second via 118, the first power wiring 121 and the fourth power wiring 132 can be prevented from being electrically shorted with the first data signal wiring 133, and the second power wiring 122 and the third power wiring 131 can be prevented from being electrically shorted with the second data signal wiring 134.

Through the aforementioned arrangement structure, a low-potential voltage may be supplied through the first power wiring 121 on the lower surface of the substrate 110 at the left side of the driving IC 140 or the light-emitting element, and a low-potential voltage may be supplied through the fourth power wiring 132 on the upper surface of the substrate 110 at the right side thereof. In addition, a high-potential voltage may be supplied through the third power wiring 131 on the upper surface of the substrate 110 at the left side of the driving IC 140 or the light-emitting element, and a high-potential voltage may be supplied through the second power wiring 122 on the lower surface of the substrate 110 at the right side thereof.

Since the first connecting part 127 makes the low-potential voltage supplied to the first power wiring 121 and the low-potential voltage supplied to the fourth power wiring 132 the same, the first connecting part 127 may be a first equipotential power wiring. Since the second connecting part 128 makes the high-potential voltage supplied to the second power wiring 122 and the high-potential voltage supplied to the third power wiring 131 the same, the second connecting part 128 may be a second equipotential power wiring.

Meanwhile, the third power wiring 131 may be electrically connected to the driving IC 140, and the fourth power wiring 132 may be electrically connected to the driving IC 140 and the light-emitting element chip 150.

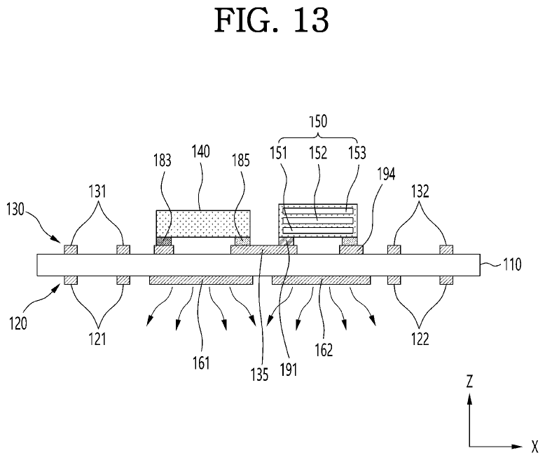

FIG. 13 is a cross-sectional view of a transparent display device according to a second embodiment.

The second embodiment is the same as the first embodiment (FIG. 1) except for a heat diffusion layers 161 and 162. In the second embodiment, components having the same shape, structure, and/or function as those in the first embodiment (FIG. 1) are given the same drawing reference numerals, and detailed descriptions are omitted. The omitted description regarding the second embodiment below may be easily understood from the description of the first embodiment (FIG. 1).

As illustrated in FIG. 13, the heat diffusion layers 161 and 162 may be disposed on the lower surface of the substrate 110. The heat diffusion layers 161 and 162 can serve to quickly release heat generated from the driving IC 140 and/or the light-emitting element chip 150 to the outside. The heat diffusion layers 161 and 162 may be formed of a material having excellent heat dissipation characteristics. For example, the heat diffusion layers 161 and 162 may be formed of a metal having excellent heat dissipation characteristics, such as aluminum. The heat diffusion layers 161 and 162 may be heat dissipation plates.

The heat diffusion layers may comprise a first heat diffusion layer 161 on a lower surface of the substrate 110 corresponding to the driving IC 140 and a second heat diffusion layer 162 on a lower surface of the substrate 110 corresponding to the light-emitting element chip 150. The first heat diffusion layer 161 can quickly release heat generated from the driving IC 140 to the outside, and the second heat diffusion layer 162 can quickly release heat generated from the light-emitting element chip 150 to the outside.

Although not illustrated in the drawing, the first heat diffusion layer 161 and the second heat diffusion layer 162 may not be separated, and the heat diffusion layers 161 and 162 may be disposed to extend from a first region of the lower surface of the substrate 110 corresponding to the driving IC 140 to a second region of the lower surface of the substrate 110 corresponding to the light-emitting element chip 150. That is, the heat diffusion layers 161 and 162 may be disposed not only on the first region and the second region, but also on a third region between the first region and the second region.

Instead of the heat diffusion layers 161 and 162, a light blocking layer, a light reflecting layer, a light absorbing layer, etc. may be disposed.

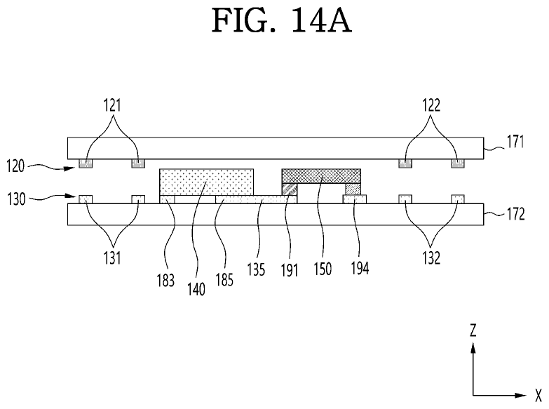

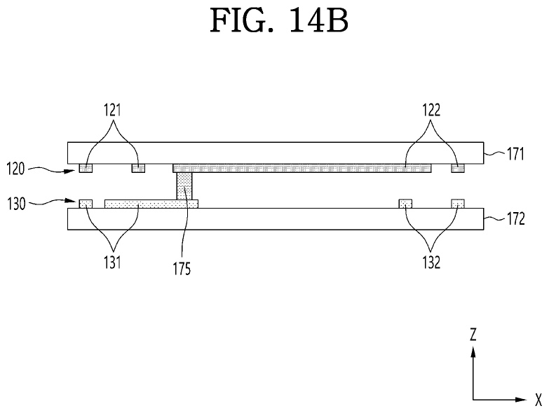

FIG. 14A is a cross-sectional view illustrating an example of a transparent display device according to a third embodiment. FIG. 14B is a cross-sectional view illustrating another example of a transparent display device according to the third embodiment.

FIG. 14A is a cross-sectional view illustrating a driving IC 140 and a light-emitting element chip 150 provided in one pixel, and FIG. 14B may be a cross-sectional view illustrating a region in which the driving IC 140 and the light-emitting element chip 150 are not disposed in one pixel.

The third embodiment is similar to the first embodiment (FIG. 1) except for a first substrate 171 and a second substrate 172. In the third embodiment, components having the same shape, structure, and/or function as those of the first embodiment (FIG. 1) are given the same drawing reference numerals, and detailed descriptions are omitted. The omitted descriptions related to the third embodiment below may be easily understood from the description of the first embodiment (FIG. 1).

Referring to FIGS. 14A and 14B, a transparent display device according to the third embodiment may comprise a first substrate 171, a second substrate 172, a first layer 120, a second layer 130, a driving IC 140, a light-emitting element chip 150, etc.

A lower surface of the first substrate 171 and an upper surface of the second substrate 172 may be disposed to face each other. In this instance, the first layer 120 may be disposed on a lower surface of the first substrate 171, and the second layer 130 may be disposed on an upper surface of the second substrate 172.

The first layer 120 may comprise a first power wiring 121, a second power wiring 122, etc., and the second layer 130 may comprise a third power wiring 131, a fourth power wiring 132, etc.

The driving IC 140 and the light-emitting element chip 150 may be disposed on the upper surface of the second substrate 172. The driving IC 140 and the light-emitting element chip 150 may be disposed between the first substrate 171 and the second substrate 172. An upper side of the driving IC 140 or an upper side of the light-emitting element chip 150 may be spaced apart from the lower surface of the first substrate 171, but is not limited thereto.

Although not illustrated, a molding part may be disposed between the first substrate 171 and the second substrate 172. The first substrate 171 and the second substrate 172 may be bonded together through the molding part, and the driving IC 140 and the light-emitting element chip 150 may be fixed through the molding part.

Meanwhile, a conductive spacer 175 may be disposed between the first substrate 171 and the second substrate 172. The conductive spacer 175 may be used instead of the first via 111, the second via 112, and the via 113 illustrated in FIG. 2, the first via 114, the second via 115, and the via 116 illustrated in FIG. 5, and the first via 117 and the second via 118 illustrated in FIG. 11.

For example, as illustrated in FIG. 14B, the first power wiring 121 and the fourth power wiring 132 may be electrically connected through the conductive spacer 175. The conductive spacer 175 may be formed of a metal or a composite material such as a resin containing metal. Instead of the conductive spacer 175, a conductive ball, solder, etc., containing metal may be used. As illustrated in FIG. 11, the first power wiring 121 and the fourth power wiring 132, to which a low potential voltage is supplied, may be electrically connected through the conductive spacer 175.

Although not illustrated, the second power wiring 122 and the third power wiring 131, to which a high potential voltage is supplied, may be electrically connected through another conductive spacer 175.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

What is claimed is:

1. A transparent display device, comprising:
a first layer comprising a first power wiring and a second power wiring along a first direction;
a second layer disposed on the first layer and comprising a third power wiring, a fourth power wiring, a first data signal wiring, a second data signal wiring, and a plurality of connecting wirings along the first direction;
a driving IC disposed between the third power wiring and the fourth power wiring; and
a light-emitting element disposed between the third power wiring and the fourth power wiring,
wherein the driving IC is electrically connected to one of the first power wiring and the third power wiring, one of the second power wiring and the fourth power wiring, the first data signal wiring, the second data signal wiring, and the plurality of connecting wirings,
wherein the light-emitting element is electrically connected to one of the second power wiring and the fourth power wiring and the plurality of connecting wirings, and
wherein the first power wiring and the third power wiring vertically overlap and the second power wiring and the fourth power wiring vertically overlap.

2. The transparent display device of claim 1, further comprising:
a substrate having a lower surface on which the first layer is disposed and an upper surface on which the second layer is disposed.

3. The transparent display device of claim 2, wherein the first power wiring and the second power wiring are low-potential wirings, and the third power wiring and the fourth power wiring are high-potential wirings.

4. The transparent display device of claim 3, wherein the first layer further comprises:
a connecting part configured to electrically connect the first power wiring and the second power wiring across the second data signal wiring along a second direction; and
a connecting pattern configured to electrically connect the third power wiring and the fourth power wiring through a first via and a second via in the substrate across the first data signal wiring along the second direction.

5. The transparent display device of claim 3, wherein the second power wiring is electrically connected to the driving IC and the light-emitting element through a via in the substrate, and the third power wiring is electrically connected to the driving IC.

6. The transparent display device of claim 2, wherein the first power wiring and the second power wiring are high-potential wirings, and the third power wiring and the fourth power wiring are low-potential wirings.

7. The transparent display device of claim 6, wherein the first layer further comprises:
a connecting part configured to electrically connect the first power wiring and the second power wiring across the first data signal wiring along a second direction; and
a connecting pattern configured to electrically connect the third power wiring and the fourth power wiring through a first via and a second via in the substrate across the second data signal wiring along the second direction.

8. The transparent display device of claim 7, wherein the connecting part is electrically connected to the driving IC through a via in the substrate, and the fourth power wiring is electrically connected to the driving IC and the light-emitting element.

9. The transparent display device of claim 2, wherein the first power wiring and the fourth power wiring are low-potential wirings, and the second power wiring and the third power wiring are high-potential wirings.

10. The transparent display device of claim 9, wherein the first layer further comprises:
a first connecting part configured to electrically connect the first power wiring and the fourth power wiring through a first via in the substrate across the first data signal wiring along a second direction; and
a second connecting part configured to electrically connect the second power wiring and the third power wiring through a second via in the substrate across the second data signal wiring along the second direction;

11. The transparent display device of claim 9, wherein the third power wiring is electrically connected to the driving IC, and the fourth power wiring is electrically connected to the driving IC and the light-emitting element.

12. The transparent display device of claim 1, further comprising:
a first substrate having a lower surface on which the first layer is disposed; and
a second substrate having an upper surface on which the second layer is disposed,
wherein the driving IC and the light-emitting element are disposed between the first substrate and the second substrate.

13. The transparent display device of claim 12, further comprising:
a conductive spacer between the first substrate and the second substrate.

14. The transparent display device of claim 1, wherein the light-emitting element comprises a plurality of light-emitting elements that are vertically stacked with each other and electrically connected to the plurality of connecting wirings.

15. The transparent display device of claim 1, wherein the light-emitting element comprises a plurality of light-emitting elements that are disposed horizontally with each other along a second direction and connected to the plurality of connecting wirings.
